(19) United States
(12) Patent Application Publication
(10) Pub. No.: US 2005/0221202 A1
(43) Pub. Date: Oct. 6, 2005

(54) Wavelength filtering in nanolithography

(76) Inventor: Kazimierz J. Gofron, DeKalb, IL (US)

Correspondence Address: Amy E. Rinaldo;Kohn & Associates, PLLC, Suite 410, 30500 Northwestern Highway, Farmington Hills, MI, 48334, US

(21) Appl. No.: 11/052,336

(22) Filed: Feb. 7, 2005

Related U.S. Application Data
(60) Provisional application No. 60/541,976, filed on Feb. 5, 2004.

(51) Int. Cl. G03F 9/00

(52) U.S. Cl. 430/5

(57) ABSTRACT

A device for creating nano-sized features on a substrate having an extreme ultra violet source, and a mask positioned between the extreme ultra violet source and a photosentive material coated substrate for limiting the wavelengths transmitted to the substrate, thereby forming nano-sized features on the substrate. A method of forming nano-sized features on a substrate by inserting a pre-designed mask between an extreme ultra violet source and a photosensitive material coated substrate, and illuminating the extreme ultra violet source through the mask onto the substrate, thereby etching the nano-features onto the substrate.

### CROSS-REFERENCE TO RELATED APPLICATIONS

This application claims the benefit of priority under 35 U.S.C. Section 119(e) of U.S. Provisional Patent Application No. 60/541,976, filed Feb. 5, 2004, which is incorporated herein by reference.

### BACKGROUND OF THE INVENTION

1. Technical Field

The present invention relates to wavelength filtration. More specifically, the present invention relates to wavelength filtration for nano-lithography.

2. Background Art

Photolithography and photomasking to generate a device pattern on a substrate base have been an essential part of fabrication of semiconductor devices. A photolithographic device fabrication process is based on masking those regions of the substrate base which are not to be etched with a photoresist mask. The base material is etched away from those regions which are not protected by a photoresist mask. The etching produces, on the fabrication surface, ditches or recesses whose depths are dependent on the duration of etching.

The processing steps generally involved in the conventional technique based on the use of photoresist masking are disclosed below. First, the surface of a substrate base is coated with a photoresist material. Then, ultraviolet light is radiated on the photoresist material through a photomask placed on top of the coated base, thereby transferring device patterns formed in the photomask to the photoresist material. Next, the photoresist material exposed by the photomask is removed in a photographic development process to leave behind only the unexposed regions of the photoresist material on the base. Unisotropical etching can then be carried out to remove the base material from the fabrication surface using ions or radicals in a plasma etching process on the bare regions of the base not protected by the photoresist material. Finally, the photoresist material is removed. All five steps are essential in the conventional technique to duplicate the pattern of the photomask using photolithography to form ultra-fine ditches or recesses in the surface of the base. In general, it is necessary to repeat the basic five steps a number of times to form ditches of different depths in the base before an operative semiconductor device can be produced.

Throughout the process of conventional microfabrication, various photomasks having different complex photoresist patterns are absolutely essential. If lines or holes in the range of 1 μm or less are required in the photomasks, special equipment and effort are required, and both capital and labor expenses associated with the technique are rather high. Even with the best of equipment, the technique is basically not adaptable to microfabrication in the range of nanometers. Also, for the technique to be practical, the photoresist material must respond to ultraviolet light or electron beams, thereby limiting the choice of photoresist material that can be used. Further, the use of the technique is not allowed when there is a danger of the photoresist material becoming a contaminant. The success of photolithography is predicated on precise flatness of the surface of the substrate base so that the entire fabrication surface lies on a flat plane, to enable uniform fabrication of the entire surface of the substrate base. When the fabrication surface lacks flatness or smoothness, it is not possible to produce a photoresist film of high uniformity and to produce a precise exposure over the entire surface thus adding another difficulty or problem to the current methodology.

When using the conventional plasma etching process to produce patterns of less than 1 μm in size, because of the collision among the gas particles and charge accumulation on the resist material, too many of the charged particles are deviated from linearity, and strike the surface at some non-perpendicular angles to the surface. Under such conditions, it is difficult to produce deep vertical ditches or recesses having a high aspect ratio (a ratio of depth to width), and furthermore, it is nearly impossible to manufacture three-dimensional structural patterns having a width of less than 1 μm.

It would therefore be beneficial to develop a lithography method and device that can both successfully and easily be used to create patterns of less than 1 μm in size.

### SUMMARY OF THE INVENTION

According to the present invention, there is provided a device for creating nano-sized features on a substrate having an extreme ultra violet source, and a mask positioned between the extreme ultra violet source and a photosentive material coated substrate for limiting the wavelengths transmitted to the substrate, thereby forming nano-sized features on the substrate. A method of forming nano-sized features on a substrate by inserting a pre-designed mask between an extreme ultra violet source and a photosensitive material coated substrate, and illuminating the extreme ultra violet source through the mask onto the substrate, thereby etching the nano-features onto the substrate is also provided.

### DESCRIPTION OF THE DRAWINGS

Other advantages of the present invention are readily appreciated as the same becomes better understood by reference to the following detailed description, when considered in connection with the accompanying drawings wherein:

FIG. 1 is a diagram showing how wavelengths smaller than the aperture size are transmitted through the mask;

FIG. 2 is a diagram showing the general principle of extreme ultra violet lithography;

FIG. 3 is a diagram showing the fabrication of a nano-wire assembly; and

FIG. 4 is a diagram showing the fabrication of a nano-dots assembly.

### DESCRIPTION OF THE INVENTION

Generally, the present invention provides a method and device for creating small features/devices of a surface of a substrate using modified lithography at short wavelengths. More specifically, the present invention provides a method and device for creating the features on the surface of a substrate on a nano-meter-scale.

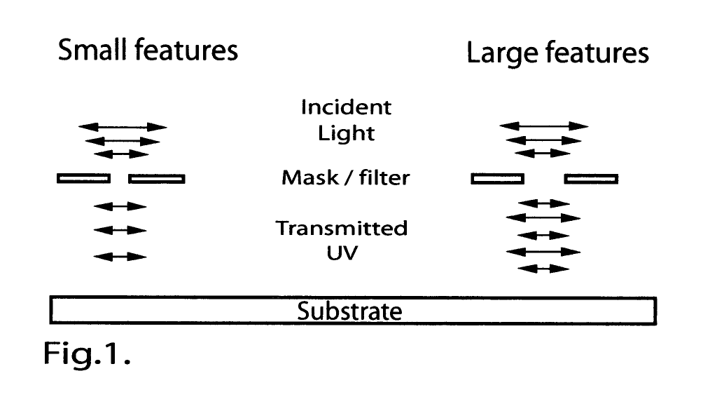

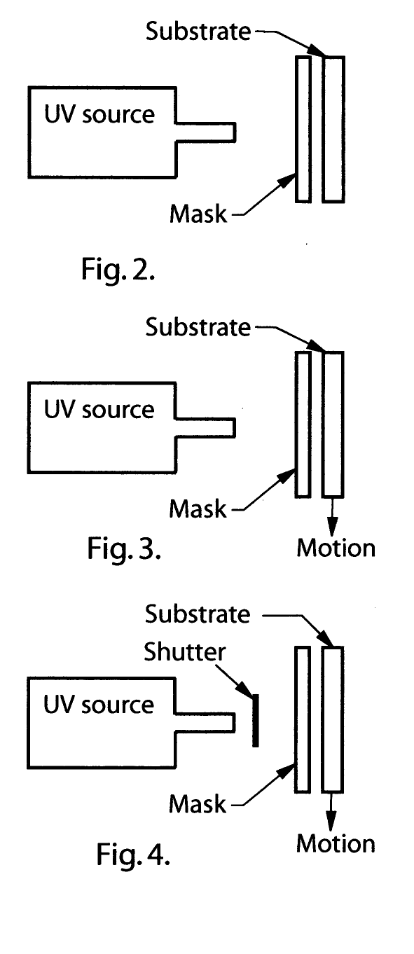

The operational principle is shown in FIGS. 1 and 2. The substrate 10 is illuminated by the EUV source 12 through the mask 14. The features 16 of the mask 14 are reproduced on the substrate 10. The features 16 can later be developed into functional devices. The method and device of the present invention differs from that of the prior art because of the light source. The use of EUV enables use of a high energy photon beam that is able to create small features on a substrate surface, this cannot be done using the current methodologies.

The term “lithography” as used herein is intended to be a process for creating chemical patterns on a surface. The method is widely employed by the semiconductor industry to pattern the surface of silicon wafers, the stone out of which computer chips are made.

The substrate is any substrate onto which a material can be applied in the manner disclosed above. Examples of such substrates are known to those of skill in the art and can include, but are not limited to, sensors, memory devices, optical gratings, zone plates, and electronic circuits. The substrate is coated with a photosensitive material. One example of the photosensitive material is silver bromide crystals. Other materials can be used without departing from the spirit of the invention.

The extreme ultra-violet (hereinafter “EUV”) of the present invention is any EUV known to those of skill in the art that can produce a significant photon beam. Examples of such sources are known to those of skill in the art and can include, but are not limited to, a helium lamp or other UV source capable of producing significant intensity at 58.4 nm. The photons can also be produced by pulsed discharge, excimer laser based (clusters of Krypton) source, or other broadband UV source. Additionally, the photon source can include a focusing elliptic mirror or other optics to enhance the intensity of the UV source by either focusing the photons on the substrate or removing undesired wavelengths prior to impacting the mask. Other properties, such as polarization of UV light can be used to simplify creation of smaller features.

The mask of the present invention is a device that includes holes, and/or slots with a diameter slightly larger than the wavelength of interest, wherein the holes are formed in a design to create the desired feature as shown in the Figures. The wavelength filtering, in present invention, occurs primarily in the mask. Such mask selects from many wavelengths present in the source such that only the short wavelengths necessary for creation of small features are allowed through the mask. However, “Large” features can be created by allowing both long and short wavelengths through the mask. For example, when a circular hole of 60 nm in the mask is illuminated, the features can be created with a wavelength of 58.4 nm. Longer wavelengths are not transmitted to the substrate. Wavelengths shorter than 58.4 nm can be present in the transmitted beam, however the shorter wavelengths do not degrade the resolution/sharpness of the features created. The mask is formed using materials and technology known to those having skill in the art. Examples of materials include, but are not limited to, an electron beam and an ion beam.

The device of the present invention enables use of broadband source with a wide range of wavelengths. By utilizing a wide range of wavelengths a number of differently sized features can be created. Short wavelengths can be used to create small features and both short and longer wavelengths can be used to create larger features. The device masks the longer wavelengths and thus only allowing the shorter wavelengths to pass though the filter, thereby creating smaller features. By masking the longer wavelengths, the device enables small features to be created without degrading the sharpness/resolution of the features.

The device functions as follows. The substrate unto which the feature/material is being deposited is illuminated by a EUV source through a mask. The features included in the mask are then reproduced on the substrate and are later developed into functional devices.

Fabrication of structures of nanometer dimensions has recently attracted increasing interest because of the utilization for functional devices. Nano-materials exhibit properties that are unique and sometimes enhance desired phenomena of bulk materials. In addition, due to the small size, more functional devices can be placed in a unit area than can be placed in devices formed using conventional lithography techniques. Further, the wavelength filtering of the present invention can be used with either a conventional EUV glow discharge source for a simple setup, or very elaborate multi-wavelength research systems.

The method of the present invention allows the creation of small features, devices, or sensors that are tens of nanometers in size. Examples of optical and electronic devices that can be produced using the method and device of the present application include, but are not limited to, small sensors (pressure, magnetic field, torque, stress, etc.), memory devices (MRAM, spintronic devices), optical gratings, zone plates for UV and x-ray applications, quantum dots, quantum wires, and “coherent electronic circuits.

For example, FIG. 3 shows the fabrication of a nano-wire assembly. In order to form a nano-wire assembly the mask contains a line of pinholes with diameters slightly larger than the wavelength of interest. The substrate is move perpendicular to the line of pinholes, thus activating the photoresists/photosensitive material in the area of the quantum wire.

Additionally, FIG. 4 shows the fabrication of a nano-dot assembly. In order to form a nano-dot assembly the mask contains a line of pinholes with diameters slightly larger than the wavelength of interest. The substrate is move perpendicular to the line of pinholes. Simultaneously, a shutter 20 allows activation of the photoresists/photosensitive material in the area of the quantum dot.

Throughout this application, author and year, and patents, by number, reference various publications, including United States patents. Full citations for the publications are listed below. The disclosures of these publications and patents in their entireties are hereby incorporated by reference into this application in order to more fully describe the state of the art to which this invention pertains.

The invention has been described in an illustrative manner, and it is to be understood that the terminology that has been used is intended to be in the nature of words of description rather than of limitation.

Obviously, many modifications and variations of the present invention are possible in light of the above teachings. It is, therefore, to be understood that within the scope of the described invention, the invention may be racticed otherwise than as specifically described.

1. A device for creating nano-sized features on a substrate, said device comprising:
an extreme ultra violet source, and
masking means positioned between said extreme ultra violet source and a photosentive material coated substrate for limiting the wavelengths transmitted to the substrate, thereby forming nano-sized features on the substrate.

2. The device according to claim 1, wherein said extreme ultra violet source is a device capable of forming a range of wavelengths of photon beams.

3. The device according to claim 2, wherein said extreme ultra violet source is selected from the group consisting essentially of a helium lamp and a broadband UV source.

4. The device according to claim 2, wherein said extreme ultra violet source further includes focusing means for focusing the photons from said extreme ultra violet source.

5. The device according to claim 4, wherein said focusing means is a focusing elliptic mirror.

6. The device according to claim 1, wherein said masking means is selected from the group consisting essentially of an electron beam and an ion beam.

7. The device according to claim 1, wherein said masking means includes holes for allowing desired extreme ultra violet wavelengths to pass therethrough.

8. A method of forming nano-sized features on a substrate, comprising the steps of:
inserting a pre-designed mask between an extreme ultra violet source and a photosensitive material coated substrate, and
illuminating the extreme ultra violet source through the mask onto the substrate, thereby etching the nano-features onto the substrate.

9. The method according to claim 8, further including forming a mask containing therein a design.

10. The method according to claim 8, further including coating a substrate with a photosensitive material.

11. A substrate having nano-sized features formed by the method of claim 8.

12. The substrate according to claim 11, wherein said substrate is selected from the group consisting essentially of sensors, memory devices, optical gratings, zone plates, and electronic circuits.

13. The substrate according to claim 11, wherein said substrate is coated with a photosensitive material.

14. The substrate according to claim 13, wherein said coating is selected from the group consisting essentially of silver bromide crystals.

15. A device for creating nano-sized features on a substrate, said device comprising:
an significant photon beam source, and
masking means positioned between said extreme ultra violet source and a photosentive material coated substrate for limiting the wavelengths transmitted to the substrate, thereby forming nano-sized features on the substrate.
